(19) United States
(12) Patent Application Publication
(10) Pub. No.: US 2016/0034008 A1
(43) Pub. Date: Feb. 4, 2016

(54) SYSTEM AND METHOD FOR A MODULAR BENCHTOP CHASSIS

(71) Applicant: RADX Technologies, Inc., Palo Alto, CA (US)

(72) Inventors: Ross Quentin Smith, Palo Alto, CA (US); Robert Wade Lowdermilk, JR., San Diego, CA (US); Christopher Dana O'Brien, San Diego, CA (US)

(73) Assignee: RADX Technologies, Inc., Palo Alto, CA (US)

(21) Appl. No.: 14/817,106

(22) Filed: Aug. 3, 2015

Related U.S. Application Data
(60) Provisional application No. 62/033,042, filed on Aug. 4, 2014.

(51) Int. Cl. G06F 1/20; H05K 13/04

(52) U.S. Cl. CPC G06F 1/20; H05K 13/04

(57) ABSTRACT

This invention relates generally to modular instrument chassis and more particularly to benchtop and rack mount modular instrument chassis that employ the PXI and PXIe standards. The present invention combines the benefits of the PXI/PXIe systems without the drawbacks that preclude PXI/PXIe systems from being used effectively in a deployable environment. Embodiments of the present invention enable PXI/PXIe systems to be deployed in a benchtop or rack mount deployable environment and enable front-to-back cooling, flexible I/O (front and back I/O panels), consistent I/O on front and back panels for reproducible and repeatable connections to external devices and for calibration requirements associated with such environments while maintaining the modularity benefits of PXI/PXIe and without sacrificing PXI/PXIe slots.

### CROSS-REFERENCE TO RELATED APPLICATIONS

This application claims priority under 35 U.S.C. §119(e) to Provisional Application No. 62/033,042, filed Aug. 4, 2014, which application is hereby incorporated herein by reference in its entirety.

### BACKGROUND

A. Technical Field

This invention relates generally to modular instrument chassis and more particularly to benchtop and rack mount modular instrument chassis for PXI and PXI Express standards.

B. Background of the Invention

PCI (Peripheral Component Interconnect) eXtensions for Instrumentation (PXI) and PXI Express (PXIe), which is an adaptation of PCI Express to the PXI form factor, are popular standards for modular instrumentation. PXIe increases the available system data rate to 6 GByte/s in each direction over PXI. Future versions of PXIe can employ newer versions of PCI Express to increase system data rates beyond 6 GBytes/s. PXI Express also allows for the use of hybrid slots, compatible with both PXI and PXI Express modules. With its Deutsches Institut für Normung (DIN) style rail guides, widespread industry support by the PXI System Alliance, interoperability and ease-of-insertion, PXI and PXIe based modular instruments have become a leading choice for modular instrumentaton—especially for prototype and lab-oriented applications.

PXI/PXIe modules themselves, because of their modularity, interoperability and relative level of ruggedness are well suited for deployable or production applications, including benchtop and rack mount deployable or production applications; however prior art PXI/PXIe enclosures do not have the features that make a deployable or production system viable.

In general, PXI/PXIe enclosures are optimized for lab use. Accordingly, employing PXI/PXIe prior art chassis in production and deployable benchtop and commercial rack mount applications is impractical, in part because the prior art chassis do not support front-to-back cooling, which is required in many production and deployable applications. There are prior art chassis where some PXI/PXIe slots, which would normally be used to house PXI/PXIe modules, are sacrificed so that the slots may be fitted with vents and used for air intake. However, those arrangements preclude the use of the sacrificed slots for functional PXI/PXIe modules, which is an imprudent use of precious PXI/PXIe slots and thereby limits the functions supported in a given PXI/PXIe system just to accommodate front-to-back cooling. In addition, such an approach that employs PXI/PXIe slot based air vents would require the use of a custom back plane with fans or vents in it, which is also not standard and adds additional cost and is incompatible with other PXI/PXIe products in the market.

Prior art PXI/PXIe enclosures typically employ an open design in which the PXI/PXIe modules themselves actually provide a primary front panel interface access for the enclosure, so that the primary I/O for the associated system comes from the PXI/PXIe modules themselves. In many cases, especially for production rack mount applications, it is desirable for all or part of the I/O to be presented at the rear of the system to allow ready and efficient interconnects with other systems in the same rack or in adjacent racks. Rear wiring with conventional PXI/PXIe chassis requires routing signals through the backplane, which necessitates customization of the PXI/PXIe modules and the backplane itself. This customization is expensive and non-standard, and it can result in sacrificing some of the PXI/PXIe slots (and employing a custom backplane) to route actual wires through the backplane area to the rear of the chassis, or routing the signals external to the chassis, which is inefficient and error prone and, in some cases, may be hazardous, depending on the signal type.

Also, prior art PXI/PXIe chassis, because of their open nature, do not readily enable the use of filtering and switching for signals that are upstream or downstream of the PXI/PXIe modules that enables the use of a consistent, connectorized front and/or rear I/O panel to facilitate repeatable and reproducible connections to external devices and which facilitates software switching and filtering in order to change routing of signals without actually changing the physical connections on the PXI/PXIe modules themselves or sacrificing PXI/PXIe slots to provide the switching and filtering. In production environments, where consistency of the interface between the PXI/PXIe modules and external devices is critical, and where user “shuffling” of cables is neither desired nor accepted, the prior art chassis are not workable

Also, prior art PXI/PXIe chassis, because of their open nature, and their intrinsic ability to have the PXI/PXIe module front panel interconnects and cables moved, tightened and loosened, all of which affect interconnect impedance and therefore system performance, especially for radio frequency (RF) or microwave applications, do not intrinsically facilitate certified calibration, usually designated with a calibration sticker, that indicates the instrument has been calibrated to be traceable to standards and that, for the calibration period, should remain within specifications, provided the calibrated connections do not change and provided that nothing within the system otherwise changes. Because a user can easily change, tighten or loosen connections on a prior art PXI/PXIe chassis front panel, such certified calibration and the use of a calibration seal or sticker across the solitary opening of the chassis makes calibration impractical or impossible.

In summary, what is needed is an improvement to PXI/PXIe enclosures to allow for optimal use in deployable and production benchtop and rack mount environments.

### BRIEF DESCRIPTION OF THE DRAWINGS

Reference will be made to embodiments of the invention, examples of which may be illustrated in the accompanying figures. These figures are intended to be illustrative, not limiting. Although the invention is generally described in the context of these embodiments, it should be understood that it is not intended to limit the scope of the invention to these particular embodiments.

FIG. 1A shows a prior art PXI/PXIe system without PXI/PXIe modules inserted.

FIG. 1B shows a prior art PXI/PXIe system with PXI/PXIe modules inserted.

FIG. 2 shows a flowchart of a manufacturing process for producing or improving a PXI/PXIe chassis for production or deployable benchtop or rack mount use.

FIG. 3A shows a view illustrating features of the improved PXI/PXIe chassis, in accordance with various aspects of the present invention.

FIG. 3B shows another view illustrating features of the improved PXI/PXIe chassis, in accordance with various aspects of the present invention.

FIG. 3C shows another view illustrating features of the improved PXI/PXIe chassis, in accordance with various aspects of the present invention.

FIG. 4 shows a block diagram showing several aspects of the present invention including the front-to-back air flow in a PXI/PXIe chassis, in accordance with various aspects of the present invention.

FIG. 5 shows an illustration of the PXI/PXIe chassis in a rack mount, in accordance with various aspects of the present invention.

FIG. 6 shows an illustration of a front view of a PXI/PXIe chassis, in accordance with various aspects of the present invention.

FIG. 7 shows an illustration of a front view of a PXI/PXIe chassis, in accordance with various aspects of the present invention.

FIG. 8 shows an illustration of a rear view of a PXI/PXIe chassis, in accordance with various aspects of the present invention.

FIG. 9A shows an illustration of a view of a PXI/PXIe chassis, in accordance with various aspects of the present invention.

FIG. 9B shows an illustration of a view of a PXI/PXIe chassis, in accordance with various aspects of the present invention.

FIG. 9C shows an illustration of a view of a PXI/PXIe chassis, in accordance with various aspects of the present invention.

FIG. 10 shows an illustration of a view of a PXI/PXIe chassis showing connectivity, in accordance with various aspects of the present invention.

FIG. 11 shows an illustration of a top view of a PXI/PXIe chassis, in accordance with various aspects of the present invention.

FIG. 12 shows an illustration of one embodiment of a close up view of a PXI/PXIe chassis, in accordance with various aspects of the present invention.

FIG. 13 shows an illustration of one embodiment of a close up view of a PXI/PXIe chassis, in accordance with various aspects of the present invention.

FIG. 14 shows an illustration of a top view of an Internal Connector Panel or ICP, in accordance with various aspects of the present invention.

FIG. 15 shows an illustration of a Radio Frequency Interface Unit or RFIU, in accordance with various aspects of the present invention.

FIG. 16 shows an illustration of one embodiment of a front view of a PXI/PXIe chassis, in accordance with various aspects of the present invention.

FIG. 17 shows an illustration of one embodiment of a front view of a PXI/PXIe chassis, in accordance with various aspects of the present invention.

### DETAILED DESCRIPTION OF THE PREFERRED EMBODIMENTS

The following description is set forth for purpose of explanation in order to provide an understanding of the invention. However, it is apparent that one skilled in the art will recognize that embodiments of the present invention, some of which are described below, may be incorporated into a number of different computing systems and devices. Structures shown in the associated figures are illustrative of exemplary embodiments of the invention and are meant to avoid obscuring the invention. Furthermore, connections between components within the figures are not intended to be limited to direct connections. Rather, data between these components may be modified, re-formatted or otherwise changed by intermediary components.

Reference in the specification to “one embodiment”, “in one embodiment” or “an embodiment” etc. means that a particular feature, structure, characteristic, or function described in connection with the embodiment is included in at least one embodiment of the invention. The appearances of the phrase “in one embodiment” in various places in the specification are not necessarily all referring to the same embodiment.

Embodiments of the present invention improve the PXI/PXIe enclosure such that it can be used effectively in production and/or deployable benchtop and rack mount systems. The term enclosure is used interchangeably with the term chassis within this specification.

Prior art PXI/PXIe enclosures have open access and modularity making them well suited for laboratory applications. However, they are not conducive to production benchtop or rack mount systems due to limitations in cooling air flow, I/O location, I/O consistency and their inability to accommodate calibration and calibration seals. Production benchtop and rack mount systems, especially if they are used in telecommunications applications often employ a front-to-back cooling system because the rack has many units mounted above and below other units and because most racks are designed to exhaust hot air from the rear of the rack. Therefore, a prior art PXI/PXIe enclosure, which intakes cool air from underneath or from the side of the enclosure, cannot be readily employed in such a standard telecommunications rack without the use of special cooling provisions, such as “keep-out” areas to the top, bottom or side of the prior art PXI/PXIe enclosure to accommodate such its incompatible air-flow requirements. In benchtop applications, some users do not always respect these “keep-out” areas on the top, bottom or sides of prior art chassis, which can result in the cooling vents being blocked which will then result in overheating of the chassis and the modules and which may cause premature damage, failure or even fire. In some prior art chassis, front-to-back cooling can be achieved, but the solution involves sacrificing PXI/PXIe slots. Also, doing so requires special backplanes with fans or cooling apertures, which is expensive and non-standard, and results in the loss of precious PXI/PXIe slots for functional PXI/PXIe modules. An open front panel, affords the user ready access to the I/O on the front of the PXI/PXIe modules, means that adding filters or switching for signals that interface with the PXI/PXIe modules will require sacrificing PXI/PXIe slots or the addition of a separate, typically external switch, box or filter module, neither of which is conducive to production applications. Also, the open nature of the prior art I/O connections does not provide consistency or certainty of connection, which is essential for repeatable and reproducible use with external devices and for certified calibration.

Embodiments of the present invention improve the prior art PXI/PXIe chassis to enable the chassis to work optimally in production benchtop and rack mount systems without sacrificing or compromising PXI/PXIe functionality or modularity, including the sacrificing of PXI/PXIe slots to accommodate such improvements. The improvements include adding a hinged or removable front panel to the system, altering the cooling system to accommodate front-to-back cooling, adding to the hinged front panel (or adjacent to it) a subsystem that includes input/output (I/O) filtering and/or switching as well as a consistent, repeatable and reproducible I/O panel, providing an intrinsic remoting I/O from the front panel, filtering and switching subsystems and/or PXI/PXIe module front panels to I/O panel(s) in the rear of the enclosure (and vice-versa), and providing an intrinsic capability that fully exploits the aforementioned improvements to provide an certifiable calibration capability that supports the use of seals or stickers to provide an indication of calibration compliance.

Features that distinguish the present embodiments from prior art PXI/PXIe enclosures, include a) the provision of front-to-back cooling without sacrificing PXI/PXIe slots, which is desired or required to support rack mount equipment standards or to avoid cooling issues associated with benchtop placement; b) the provision of the intrinsic ability to easily and consistently route signals from the front panel of the PXI/PXIe modules and/or the filtering or switching capabilities described above or adjacent to I/O panel(s) located on the front or rear of the enclosure without sacrificing PXI/PXIe slots; c) the provision of the intrinsic ability of the PXI/PXIe enclosure to support filtering and switching of I/O to provide a consistent, repeatable and reproducible interface to external devices that does not affect the front panel I/O of the PXI/PXIe modules themselves while still permitting the user to readily access, remove and replace the PXI/PXIe modules from the front of the chassis and without sacrificing PXI/PXIe slots; and d) the provision of the intrinsic ability to support calibration and the use of calibration seals or stickers to traceable standards that utilizes the filtering and switching and consistent, repeatable and reproducible interfaces and a sealable entrance to the chassis for the location of the calibration seal or sticker.

Front-to-back cooling is desired and/or required for production or deployable benchtop and rack mount applications, because in such applications rack level or facility level cooling requirements or standards and personnel ergonomic requirements or standard dictate that intake air be drawn in from the front of the chassis and then exhausted out the rear of the chassis. In most conventional telecommunications equipment racks, the rack level cooling systems (and many equipment standards) require that the heated air exhaust from the rear of the rack for all of the elements mounted in the rack. In benchtop environments, having hot air blow on personnel using the equipment is not acceptable and in many cases, having personnel respect the placement of vents on the sides or tops of prior art PXI/PXIe chassis so as to not block air flow (i.e., “keep-out zones”) is impracticable and difficult to enforce. Because PXI/PXIe modules plug into a PXI/PXIe backplane, which precludes a simple front-to-back airflow scheme through the PXI/PXIe chassis, PXI/PXIe modules require bottom to top cooling. For simplicity, and to accommodate the fact that the backplane blocks front-to-back airflow, prior art PXI/PXIe chassis use side, top or bottom vents to effect the required bottom to top air flow over the PXI/PXIe modules. These side, top or bottom vents require users to exercise extreme care in the placement of the chassis to minimize the chance of foreign objects (papers, other chassis, coffee cups, clip boards, jackets, hats, etc.) from blocking the intake and exhaust vents, which often have associated with them “keep out” zones into which the user is advised nothing should be placed. Such “keep out” zones, are, in many applications, impractical and difficult to enforce in both benchtop and rack mount environments. In addition, such keep-out zones often consume precious rack space or benchtop space that could be used by additional equipment items, increase the overall footprint of the equipment suite.

Other objects and attainments together with a fuller understanding of the invention will become apparent and appreciated by referring to the following description and claims taken in conjunction with the accompanying drawings.

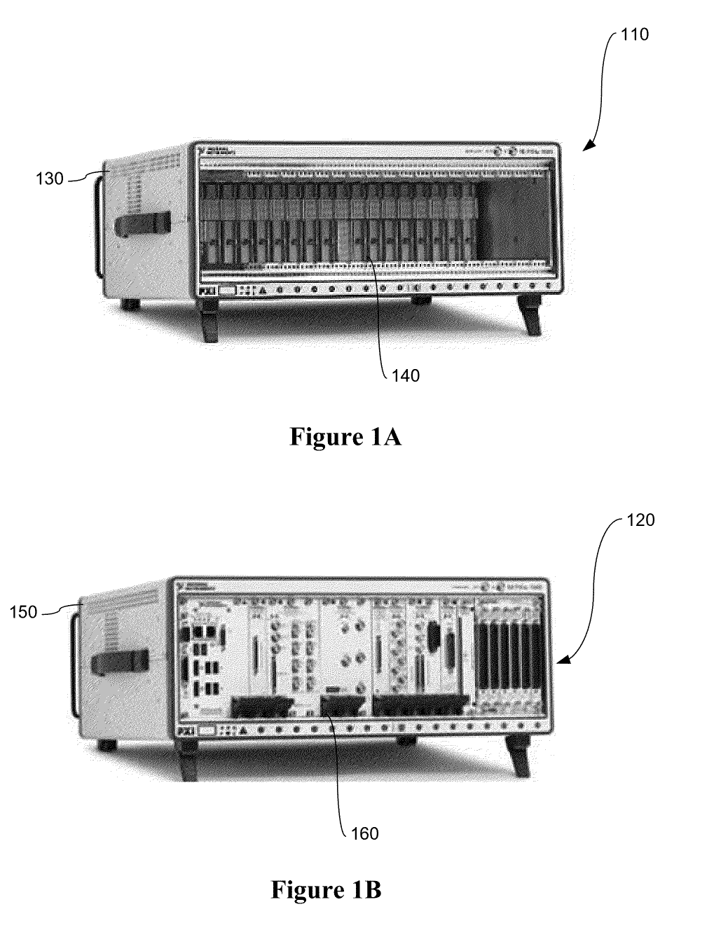

FIG. 1A shows a prior art PXIe system without PXI/PXIe modules inserted. Enclosure 110 shows an 18-slot PXI/PXIe enclosure without any modules inserted. FIG. 1A also shows side air vents 130 and an 18-slot PXI/PXIe chassis empty 140.

FIG. 1B shows a prior art PXIe system with PXI/PXIe modules inserted. FIG. 1B shows enclosure 120 shows a PXI/PXIe enclosure with modules inserted. FIG. 1B also shows air vents 15 and an 18 slot PXI/PXIe chassis full 150. The primary I/O for the prior art PXI/PXIe enclosure comes from the front panels of the PXI/PXIe modules themselves and is therefore located at the front of the prior art chassis, which precludes rear I/O access without sacrificing PXI/PXIe slots and the use of a custom backplane. It also precludes the addition of production level signal filtering and switching and precludes consistency or certainty of connection, which is essential for repeatable and reproducible operation and for certified calibration. Further, the cooling of the prior art chassis is not front-to-back.

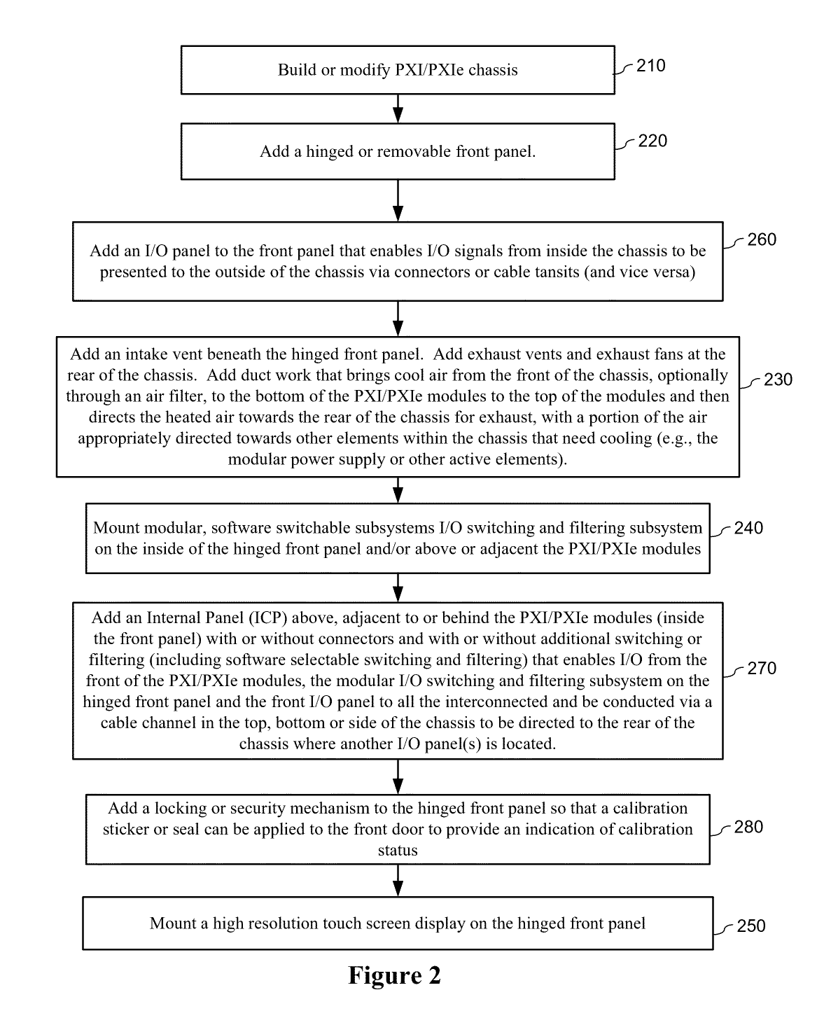

FIG. 2 shows a flowchart of a manufacturing process for manufacturing or improving a chassis for production benchtop or rack mount use. FIG. 2 shows modifying a PXI/PXIe enclosure 210. FIG. 2 also shows adding a hinged or removable front panel 220, adding an I/O panel to the front panel that enables I/O signals from inside the chassis to be presented to the outside of the chassis via connectors or cable transits (and vice versa) 260, adding an intake vent beneath the hinged front panel, add exhaust vents and exhaust fans at the rear of the chassis, adding duct work that brings cool air from the front of the chassis, optionally through a replaceable or washable air filter, to the bottom of the PXI/PXIe modules to the top of the modules and then directs the heated air towards the rear of the chassis for exhaust, with a portion of the air appropriately directed towards other elements within the chassis that need cooling (e.g., the modular power supply or other active elements) 230. FIG. 2 also shows mounting modular, software switchable signal I/O switching and filtering subsystems on the inside of the hinged front panel and/or above or adjacent to the PXI/PXIe modules 240 to support consistent I/O for connecting to external devices and for supporting calibration. FIG. 2 also shows adding an Internal Connection Panel (ICP) above the PXI/PXIe modules (inside the front panel) with or without connectors and with or without additional switching or filtering (including software selectable switching and filtering) that enables I/O from the front of the PXI/PXIe modules, the modular I/O switching and filtering subsystem on the hinged front panel and the front I/O panel to all the interconnected and be conducted via a cable channel in the top, bottom or side of the chassis to be directed to the rear of the chassis where another I/O panel(s) is located 270. FIG. 2 also shows adding a locking or security mechanism to the hinged front panel so that a calibration sticker or seal can be applied to the front door to provide an indication of calibration status 280. FIG. 2 also shows mounting a high resolution touchscreen display on the hinged front panel 250.

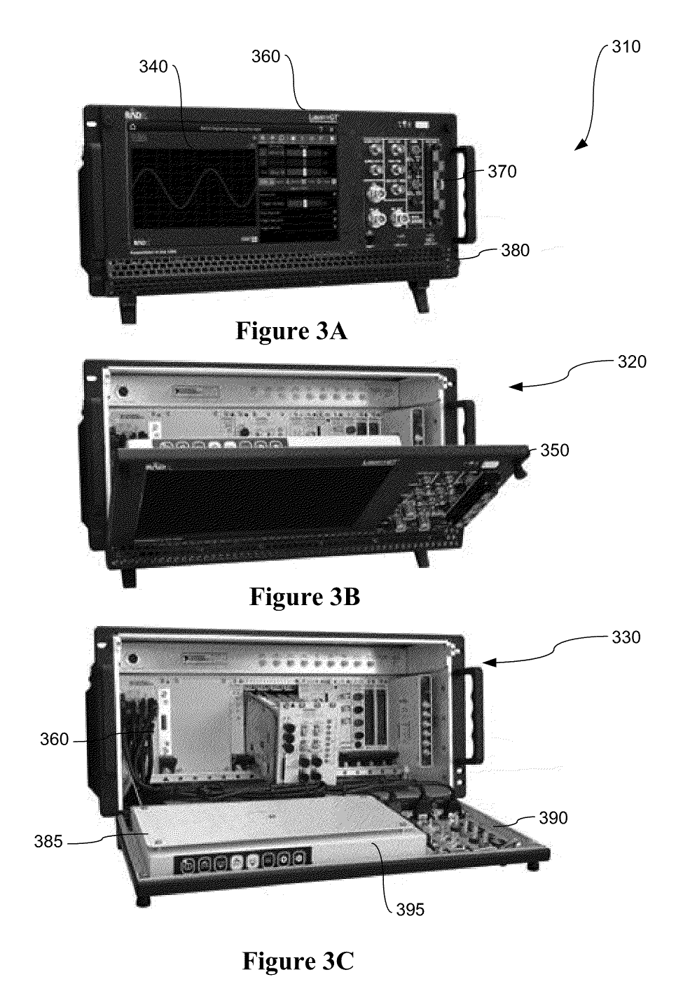

FIG. 3A shows a view illustrating features of the improved PXI/PXIe chassis, in accordance with various aspects of the present invention. FIG. 3A shows enclosure 310. Enclosure 310 illustrates the high resolution touchscreen 340 mounted on the hinged front panel. FIG. 3A also illustrates a threshold where a calibration sticker would be placed 360, the front I/O panel 370, and air intake vent 380. To enable PXI/PXIe systems to work in a benchtop or deployable environment, what is needed is a PXI/PXIe enclosure that includes some or all embodiments of the present invention. In one embodiment of the present invention, off-the-shelf PXI/PXIe card cages and backplanes are used to ensure compliance and to optimize compatibility with existing PXI/PXIe enclosures to enable rapid deployment of production systems based on prototypes developed with conventional PXI/PXIe enclosures.

FIG. 3B shows another view illustrating features of the improved PXI/PXIe chassis, in accordance with various aspects of the present invention. FIG. 3B shows enclosure 320. Enclosure 320 illustrates hinged front panel 350. While the front panel is depicted as hinged, it can also be removable in another embodiment. In one embodiment, the hinged front panel uses a retainer to preclude hinge breakage. The hinged front panel allows easy access, removal and insertion of standard PXI/PXIe modules. Hinged front panel 350 also allows the I/O interface to external devices to support both the front and rear of the chassis by means of an Internal Connector Panel (ICP) and/or a Radio Frequency Interface Unit (RFIU). The hinged front panel, combined with the air intake vent located beneath or at the bottom of the hinged front panel and ducting that directs the air appropriately also allows the cooling subsystem to be altered such that the enclosure can be cooled from front-to-back rather than bottom to top. In one embodiment, an airflow mechanism that supports front-to-back airflow for use in benchtop and standard equipment rack mount environments while preserving the standard vertical cooling approach required for standard PXI or PXIe modules can be implemented and avoiding the need to sacrifice PXI/PXIe slots for intake air and for requiring a custom backplane with fans or vents. The improved airflow mechanism reflected in the present invention has the ability to support both benchtop and rack mount applications without additional requiring additional space required for “keep-out” zones because of front-to-back cooling.

FIG. 3C shows another view illustrating features of the improved PXI/PXIe chassis, in accordance with various aspects of the present invention. FIG. 3C shows enclosure 330. Enclosure 330 illustrates the front I/O system 360. FIG. 3C also illustrates the back of the touchscreen display with no RFIU 385 and the location where a RFIU could be mounted 395. FIG. 3C also illustrates front I/O panel 390. In one embodiment, a cabling mechanism, optionally with automated switching and filtering, that enables the routing of signals from the front panel of the PXIIPXIe modules to both the front and rear panels of the enclosure can be employed. In one embodiment, a modular I/O switching and filtering subsystem mounted on the inside of the hinged front panel (or elsewhere within the front of the chassis) to provide filtering and switching of signals that need to be presented to the front panel or the rear panel of the system can be implemented. In one embodiment, a modular I/O panel on the front panel of the enclosure that enables users to readily tailor the front panel of the enclosure to meet specific application I/O needs can be implemented and to provide consistent interfaces to external devices that provide repeatable and reproducible connections. In one embodiment, a modular I/O panel on the rear panel of the enclosure that enables users to readily tailor the rear panel of the enclosure to meet specific application I/O needs can be implemented and to provide consistent interfaces to external devices. In one embodiment, the modular I/O switching and filtering, combined with the hinged front panel enables a repeatable and reproducible interface for calibration and the use of a calibration sticker or seal across the threshold of the front panel that indicates the instrument has been certified to known standards and that breaking the seal or sticker will result in compromise of calibration. In one embodiment, a Commercial Off-The-Shelf (COTS), modular power supply can make repair of the unit much more cost effective since a defective power supply may be replaced in the field as opposed to at the manufacturer's facility or repair site.

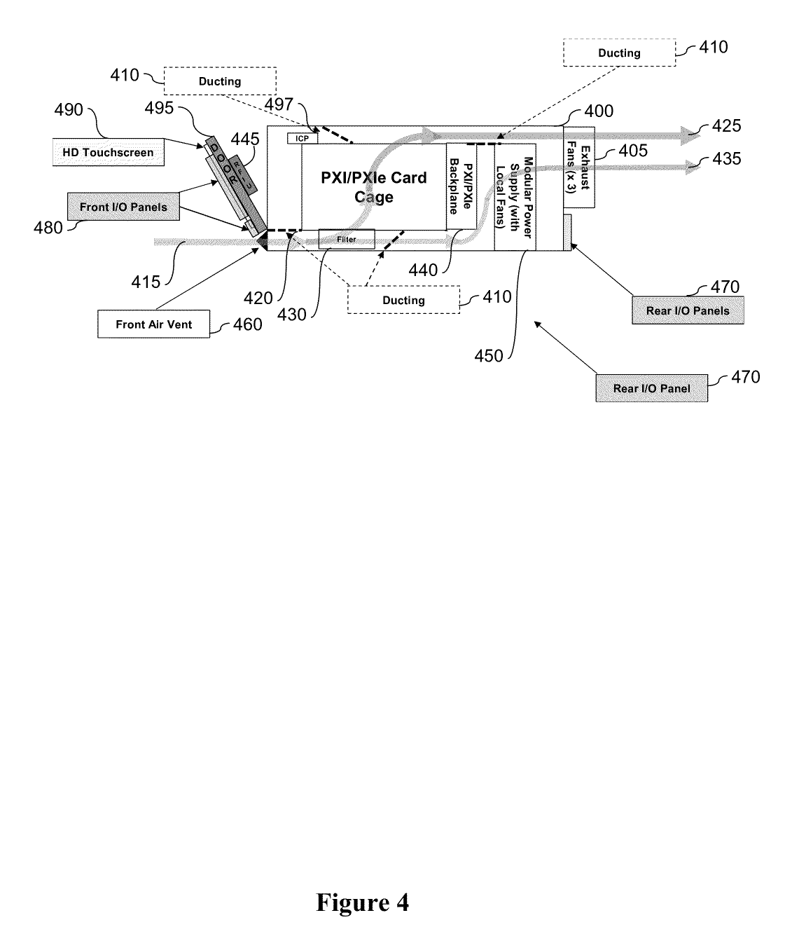

FIG. 4 shows a block diagram showing several aspects of the present invention including the improved air flow in a PXI/PXIe chassis, in accordance with various aspects of the present invention. The present invention combines the benefits of the PXI/PXIe systems without the drawbacks that preclude PXI/PXIe systems from being used effectively in a deployable or production environment. Embodiments of the present invention enable PXI/PXIe systems to be deployed in a benchtop or rack mount environment and meet the requirements associated with such environments while maintaining the modularity benefits of PXI/PXIe.

FIG. 4 shows a side view of a PXI/PXIe enclosure 400 including many embodiments of the present invention. FIG. 4 shows the PXI/PXIe card cage 420 with Internal Connector Panel (ICP)-which enables the routing of signals from the front panels of the PXI/PXIe modules to the rear of the chassis via a cable channel internal to the chassis (ICP) 497, COTS PXI/PXIe backplane 440, modular power supply with local fans 450, and filter 430. FIG. 4 also illustrates the airflow through the enclosure 400. The airflow 415 starts on the cool side at the bottom-front of the enclosure 400 with front air vent 460. In embodiments of the present invention, the air is directed towards the top and rear of the enclosure 400 and exhausts 425 and 435 the hot air out the back of the enclosure 400. FIG. 4 also illustrates the addition of ducting 410 to modify the airflow as described. FIG. 4 also illustrates the hinged front panel 495 with touchscreen 490 mounted on it and front I/O panels 480 included as well. In other embodiments, the front panel can be removable. FIG. 4 also shows Radio Frequency Interface Unit (RFIU) 445 mounted to the inside of the hinged front panel 495, which provides the modular I/O switching and filtering between the PXI/PXIe modules and the ICP and the front of the hinged front panel and which may be used to facilitate the consistent, repeatable and reproducible interface to external devices and calibration. In one embodiment, one, but not all of the modifications is implemented to provide some benefits. In another embodiment, all of the modifications of the present invention are implemented to provide the most benefit in a production, deployed environment.

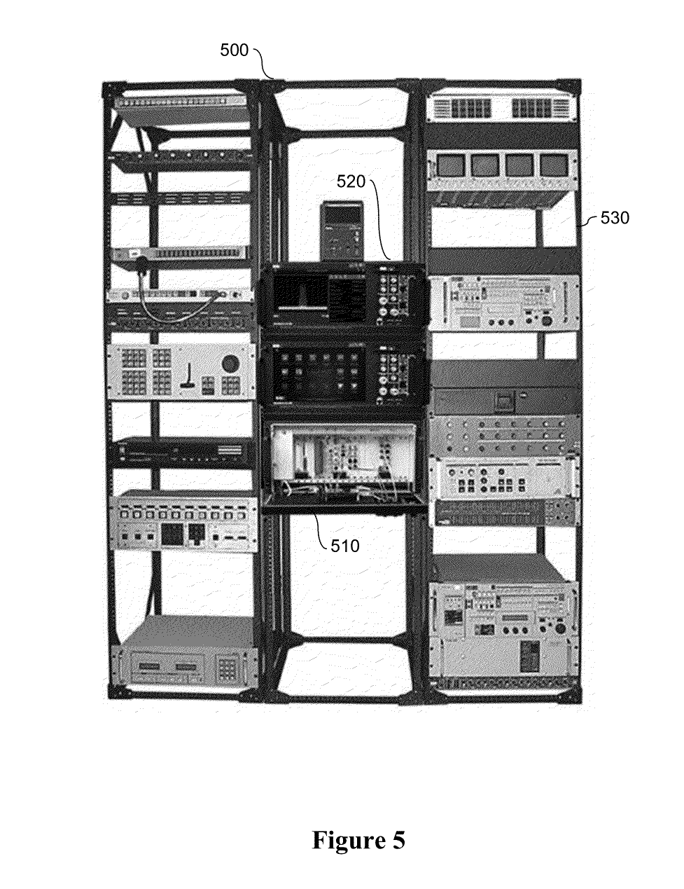

FIG. 5 shows an illustration of the PXI/PXIe chassis on a rack mount, in accordance with various aspects of the present invention. FIG. 5 shows rack mount system 500. FIG. 5 also shows that rack mount system 500 includes PXI/PXIe enclosures 520 with rack 530. One of the PXI/PXIe enclosures is illustrated with the front panel 510 open. System 500 can be utilized in accordance with the improvements made in embodiments of the present invention.

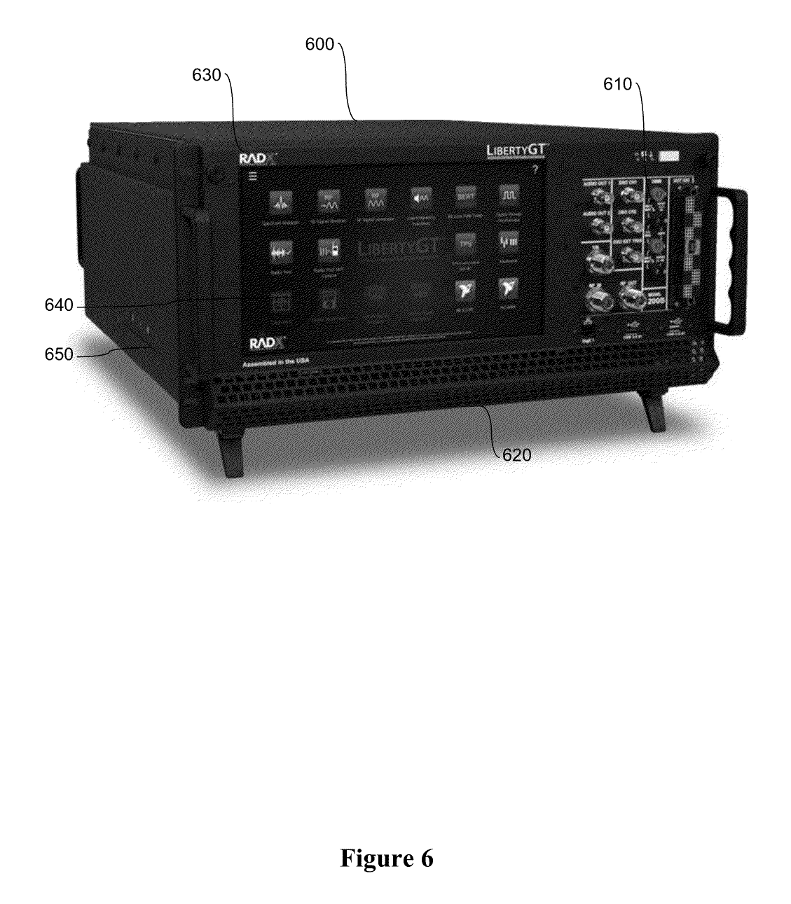

FIG. 6 shows an illustration of a front view of a PXI/PXIe chassis, in accordance with various aspects of the present invention. FIG. 6 shows one embodiment of a PXI/PXIe chassis 600 including front I/O panel for a consistent, reproducible and repeatable I/O connections to external devices 610, cool air intake vent 620, hinged door threshold where calibration sticker or seal can be placed 630, high resolution touch screen display 640, and filter for filtering intake air 650.

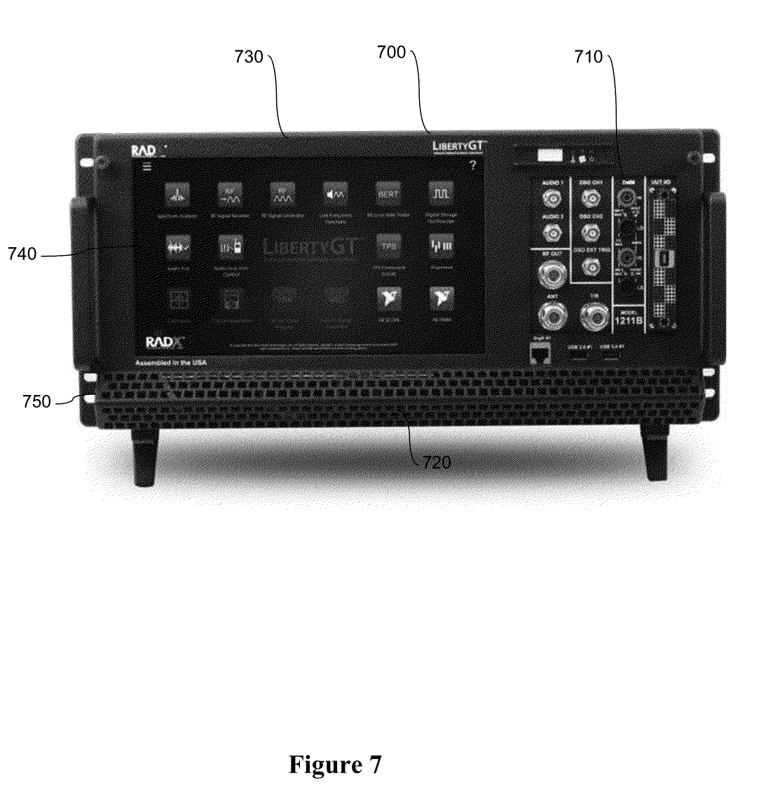

FIG. 7 shows an illustration of a front view of a PXI/PXIe chassis, in accordance with various aspects of the present invention. FIG. 7 shows one embodiment of a PXI/PXIe chassis 700 including front I/O panel for a consistent, reproducible and repeatable I/O connections to external devices 710, cool air intake vent 720, hinged door threshold where calibration sticker or seal can be placed 730, high resolution touch screen display 740, and rack mount ears 750.

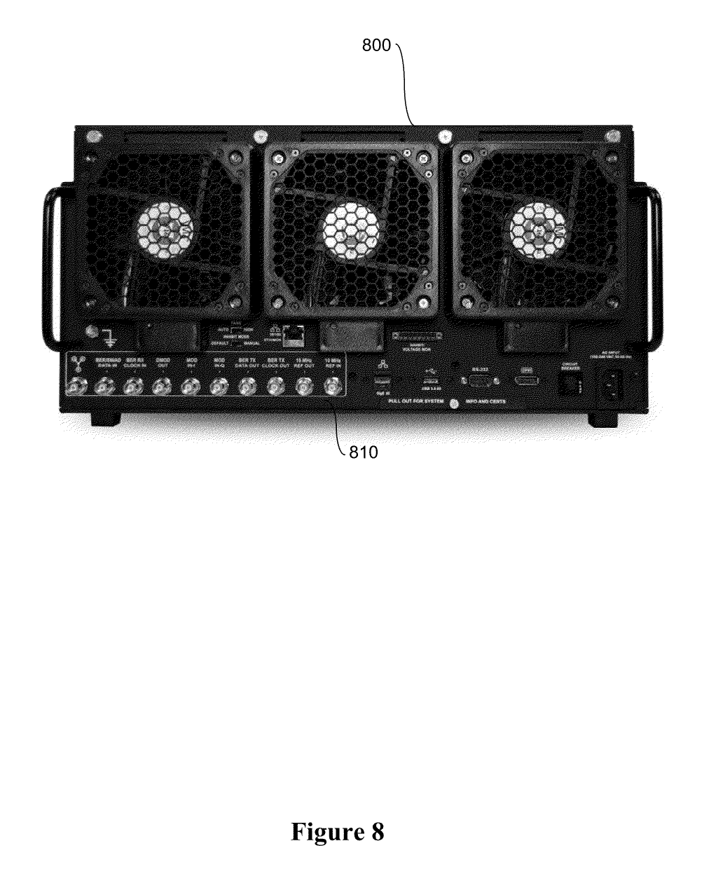

FIG. 8 shows an illustration of a rear view of a PXI/PXIe chassis, in accordance with various aspects of the present invention. FIG. 8 shows one embodiment of a PXI/PXIe chassis 800 including rear Radio Frequency (RF) I/O panel including signals from an ICP 810.

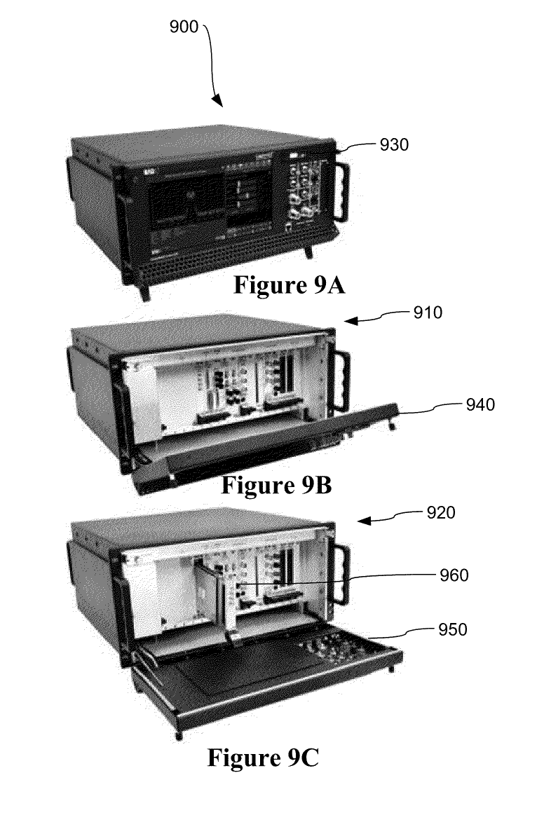

FIG. 9A shows an illustration of a view of a PXI/PXIe chassis, in accordance with various aspects of the present invention. FIG. 9A shows one embodiment of a PXI/PXIe chassis 900including hinged front panel (door) closed with the unit operating 930. In one embodiment, the hinged (or removable) front door (panel) enables cooling, connectivity and calibration benefits without sacrificing PXI/PXIe slots.

FIG. 9B shows an illustration of a view of a PXI/PXIe chassis, in accordance with various aspects of the present invention. FIG. 9B shows one embodiment of a PXI/PXIe chassis 910 including hinged front panel (door) open preparing for module replacement 940.

FIG. 9C shows an illustration of a view of a PXI/PXIe chassis, in accordance with various aspects of the present invention. FIG. 9C shows one embodiment of a PXI/PXIe chassis 920 including hinged front panel 950 (door) fully open module 960 being removed.

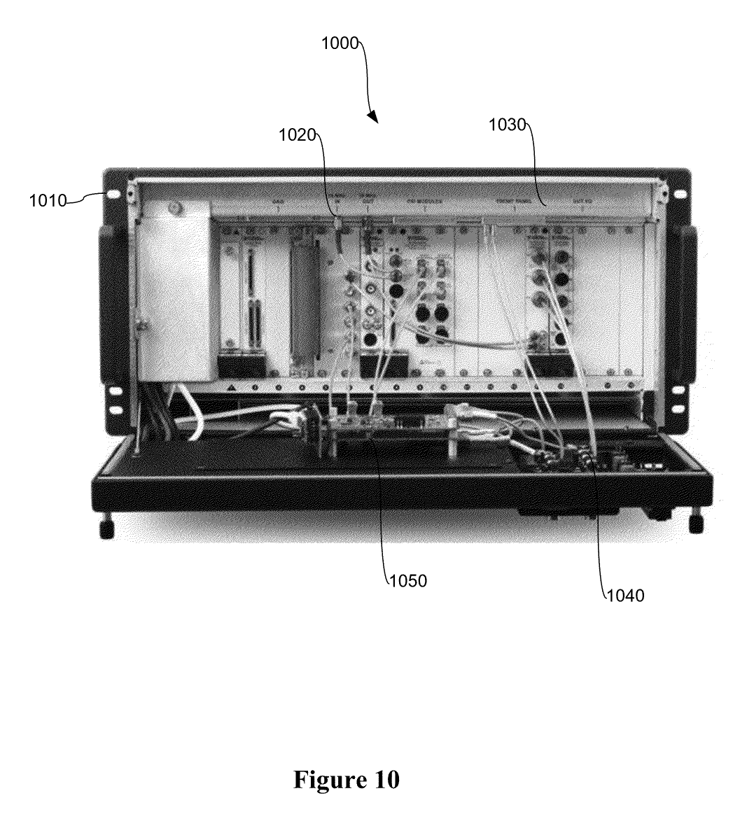

FIG. 10 shows an illustration of a view of a PXI/PXIe chassis showing connectivity, in accordance with various aspects of the present invention. FIG. 10 shows one embodiment of a PXI/PXIe chassis 1000 including rack mount ears 1010, ICP connectors 1020, Internal Connector Panel (ICP) 1030. The ICP provides switching and routing of RF signals and other signals from the front panel of the PXI/PXIe modules, enclosure of front I/O panel and RFIU to rear of enclosure. FIG. 10 also shows a front I/O panel 1040 without an optional high density UUT connector assembly. FIG. 10 also shows an RF interface unit (RFIU) 1050. The RFIU provides filtering and switching for RF signals from enclosure of front panel, front panel of PXI/PXIe modules and ICP.

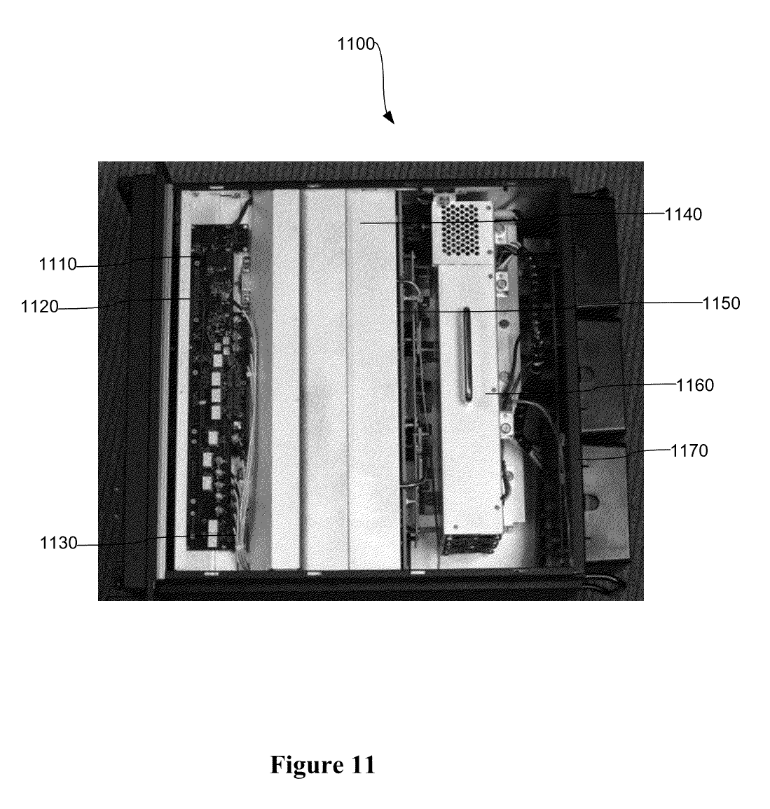

FIG. 11 shows a photograph of a top view of a PXI/PXIe chassis, in accordance with various aspects of the present invention. FIG. 11 shows one embodiment of a PXI/PXIe chassis 1100 including ICP Printed Circuit Board Assembly or PCBA for switching and filtering of signals to/from the rear panel 1110, ICP connectors above PXI/PXIe modules for connections to modules, RFIU and enclosure front panel 1120, cables from ICP going to rear I/O panel via cable channel 1130, ducting takes air from bottom of PXI/PXIe modules and directs towards rear of chassis 1140, PXI/PXIe chassis 1150, modular power supply 1160, and exhaust fans 1170.

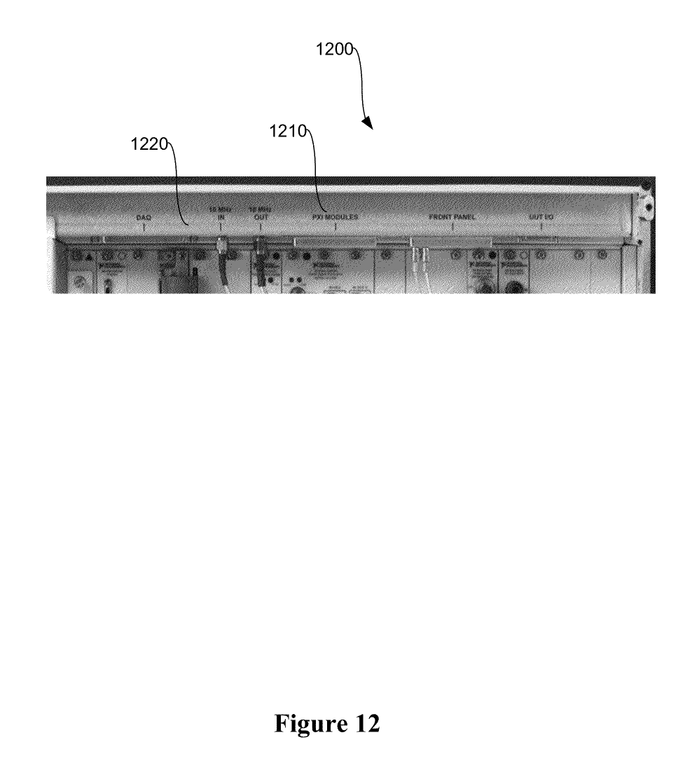

FIG. 12 shows an illustration of one embodiment of a close up view of a PXI/PXIe chassis, in accordance with various aspects of the present invention. FIG. 12 shows one embodiment of a close up view of a PXI/PXIe chassis 1200 with connectors including ICP connectors 1210 and ICP 1220. The ICP provides switching and routing of RF signals and other signals from the front panel of the PXI/PXIe modules, the front I/O panel and RFIU to the rear of enclosure.

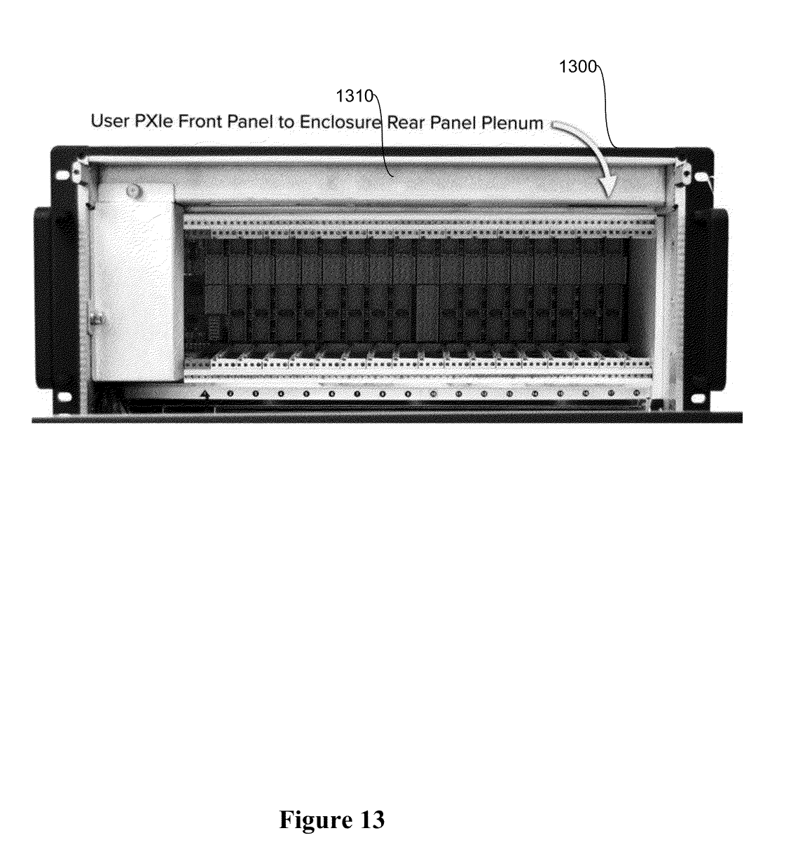

FIG. 13 shows an illustration of one embodiment of a close up view of a PXI/PXIe chassis, in accordance with various aspects of the present invention. FIG. 13 shows one embodiment of a close up view of a PXI/PXIe chassis 1300 without connectors including ICP 1310. The ICP provides switching and routing of RF signals and other signals from the front panel of the PXI/PXIe modules, enclosure of front I/O panel and RFIU to rear of enclosure.

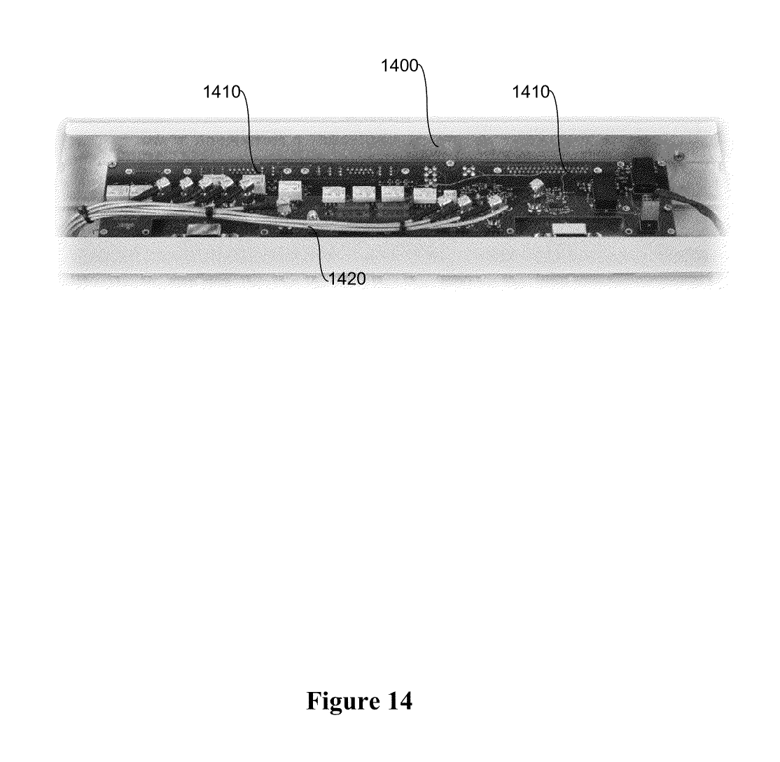

FIG. 14 shows an illustration of one embodiment of an ICP oblique top view of a PXI/PXIe chassis, in accordance with various aspects of the present invention. FIG. 14 shows one embodiment of an ICP oblique top view of a PXI/PXIe chassis 1400 including connector solder bumps 1410 showing the location of ICP connectors that appear above and forward of the PXI/PXIe modules and cable bundle 1420 headed to the rear I/O panel via cable channel.

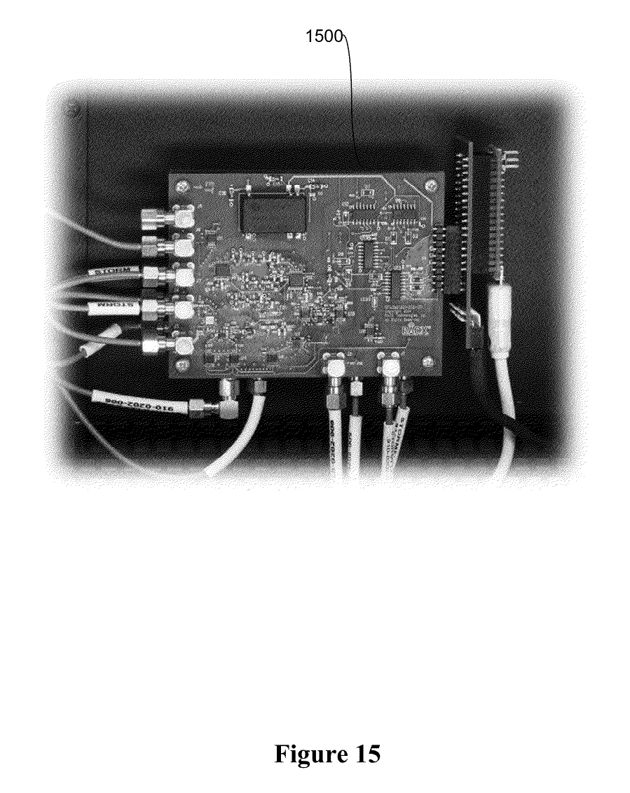

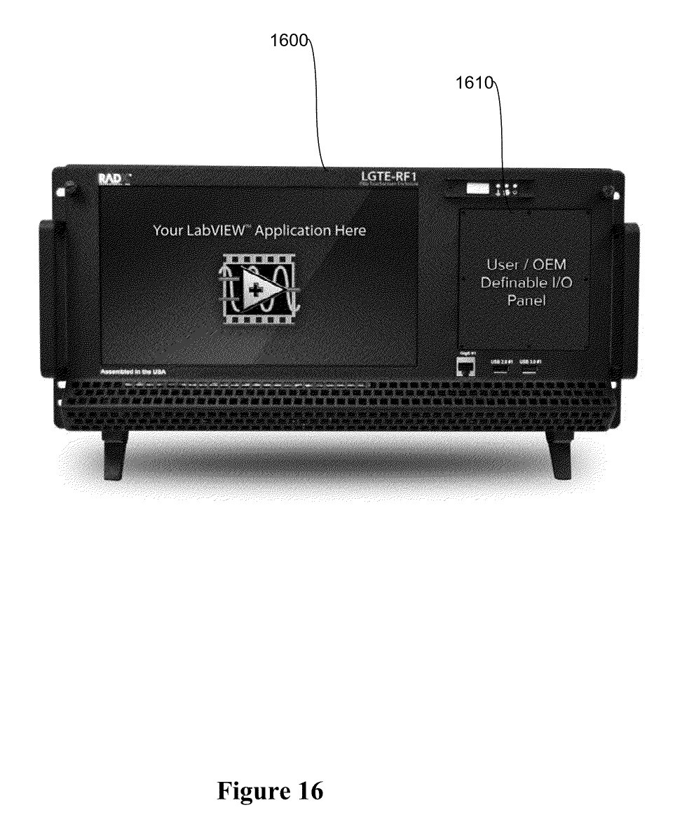

FIG. 15 shows an illustration of a RFIU, in accordance with various aspects of the present invention. RFIU 1500 can be mounted on the hinged front panel. In one embodiment, it provides signal filtering and switching, which can be controlled by software, of I/O from enclosure front panel, PXI/PXIe module front panels and ICP to provide consistent, reproducible and repeatable interface to external objects for calibration. FIG. 16 shows one embodiment of a PXI/PXIe chassis 1600 including front panel I/O 1610 left blank for user or integrator customization.

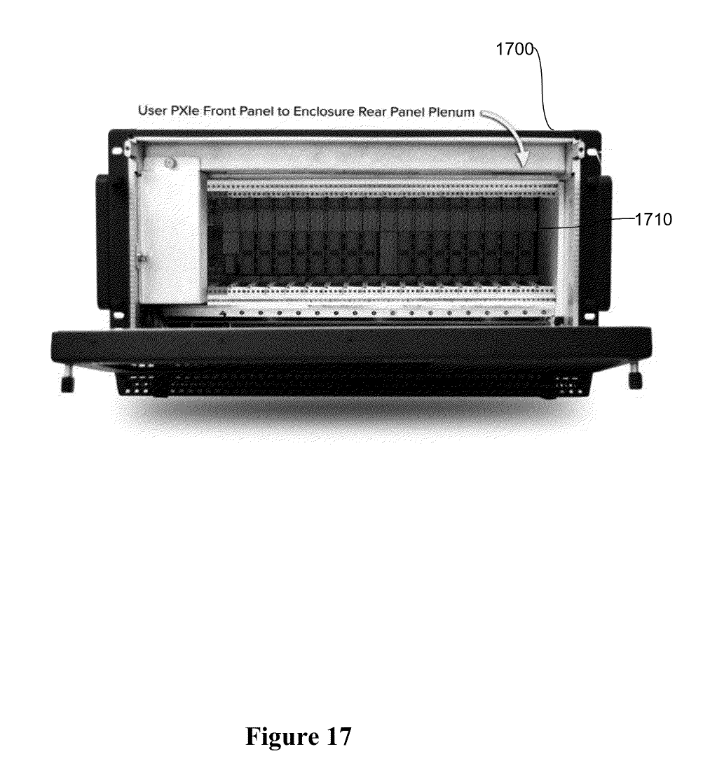

FIG. 17 shows an illustration of one embodiment of a front view of a PXI/PXIe chassis, in accordance with various aspects of the present invention. FIG. 17 shows one embodiment of a PXI/PXIe chassis 1700 including illustrating all PXI/PXIe slots 1710. One embodiment of the present invention uses a hinged front panel and improved cooling design mechanism to enable the present invention to use all the PXI/PXIe slots. In one embodiment, none of the slots are sacrificed and COTS backplane modules can be used with the present invention.

While the invention has been described in conjunction with several specific embodiments, it is evident to those skilled in the art that many further alternatives, modifications and variations will be apparent in light of the foregoing description. Thus, the invention described herein is intended to embrace all such alternatives, modifications, applications, combinations, permutations, and variations as may fall within the spirit and scope of the appended claims.

What is claimed is:

1. A PCI (Peripheral Component Interconnect) eXtensions for Instrumentation (PXI) and PXI Express (PXIe) chassis system, the chassis having a front and a rear and the ability to insert at least one PXI/PXIe module into at least one PXI/PXIe slots and having a maximum number of PXI/PXIe slots, the chassis comprising:
a front-to-back cooling system, wherein the maximum number of PXI/PXIe slots is maintained, the cooling system comprising:
a front air vent on the front of the chassis allowing cool air to enter the chassis;
a rear exhaust on the rear of chassis allowing hot air to exit the chassis; and
a ducting system coupled to the front air vent and the rear exhaust directing air flow through the chassis; and
a signal route from the front of the PXI/PXIe module to the rear of the chassis wherein the maximum number of PXI/PXIe slots is maintained.

2. The system of claim 1 further comprising an electronic system that provides filtering and/or switching of input/output signals providing an interface to an external device independent of the PXI/PXIe module.

3. The system of claim 2 wherein access to remove the PXI/PXIe modules from the front of the chassis is preserved.

4. The system of claim 1 further comprising a mechanism for accommodating the use of a calibration sticker used to seal the chassis upon calibration.

5. The system of claim 1 further comprising a hinged front panel.

6. The system of claim 1 further comprising a removable front panel.

7. The system of claim 1 further comprising a touchscreen display mounted on the front panel of the chassis.

8. A method of modifying a PCI (Peripheral Component Interconnect) eXtensions for Instrumentation (PXI) and PXI Express (PXIe) chassis, the chassis having a front and a rear and the ability to insert at least one PXI/PXIe module into at least one PXI/PXIe slots and having a maximum number of PXI/PXIe slots, the method comprising:
adding an air intake vent on the front of the chassis;
adding an air exhaust on the rear of the chassis;
connecting the air intake and the air exhaust with ducting;
routing signals from the front of the PXI/PXIe module to the rear of the chassis; and
maintaining the maximum number of PXI/PXIe slots.

9. The method of claim 8 further comprising adding a electronic subsystem that provides filtering and/or switching of input/output signals providing an interface to an external device independent of the PXI/PXIe module.

10. The method of claim 9 wherein access to remove the PXI/PXIe module from the front of the chassis is preserved.

11. The method of claim 8 further comprising providing a mechanism for sealing the chassis to indicate calibration of the system.

12. The method of claim 8 further comprising adding a hinged front panel.

13. The method of claim 8 further comprising adding a removable front panel.

14. The method of claim 8 further comprising remoting an input/output panel.

15. A PCI (Peripheral Component Interconnect) eXtensions for Instrumentation (PXI) and PXI Express (PXIe) chassis system, the chassis having a front and a rear and an input/output panel and the ability to insert at least one PXI/PXIe module into at least one PXI/PXIe slots and having a maximum number of PXI/PXIe slots, the chassis comprising:
an electronic subsystem providing filtering and/or switching of one or more input/output signals providing an interface to an external device independent of the PXI/PXIe module(s);
a calibration sticker adhered to the chassis indicative that calibration has been performed; and
a removable front panel.

16. The system of claim 15, wherein access to remove the PXI/PXIe module from the front of the chassis is preserved.

17. The system of claim 15 further comprising a front-to-back cooling system, wherein the maximum number of PXI/PXIe slots is maintained, the cooling system comprising:
a front air vent on the front of the chassis allowing cool air to enter the chassis;
a filter that filters the intake air;
a rear exhaust on the rear of chassis allowing hot air to exit the chassis; and
a ducting system coupled to the front air vent and the rear exhaust directing air flow through the chassis.

18. The system of claim 17 wherein the front-to-back cooling system further comprises an air filter.

19. The system of claim 15 wherein the removable front panel is a hinged front panel.

20. The system of claim 15 further comprising a remote an input/output panel.
